(19) United States
(12) Patent Application Publication
(10) Pub. No.: US 2025/0323083 A1
(43) Pub. Date: Oct. 16, 2025

(54) SUBSTRATE CARRYING UNIT AND SUBSTRATE PROCESSING DEVICE HAVING THE SAME

(71) Applicant: Taiwan Semiconductor Manufacturing Company, Ltd., Hsinchu (TW)

(72) Inventors: Jia-Wei TSENG, Hsinchu (TW); Hung-Chih WANG, Hsinchu (TW); Yuan-Hsin CHI, Hsinchu (TW); Sheng-Yuan LIN, Hsinchu (TW)

(73) Assignee: Taiwan Semiconductor Manufacturing Company, Ltd., Hsinchu (TW)

(21) Appl. No.: 18/631,692

(22) Filed: Apr. 10, 2024

(51) Int. Cl. H01L 21/683; B25B 11/00

(52) U.S. Cl. CPC H01L 21/6838; B25B 11/005

(57) ABSTRACT

A substrate processing device is provided, including a processing chamber and a substrate carrying unit. The substrate carrying unit is disposed in the processing chamber. The substrate carrying unit includes a vacuum chuck, a shaft part and a driving part. The vacuum chuck adsorbs and holds a substrate through a vacuum suction. The shaft part has a rotation axis, and the shaft part is configured to support the vacuum chuck. The driving part is configured to drive the vacuum chuck and the shaft part to rotate around the rotation axis, wherein the vacuum chuck has a plurality of channels with different apertures inside, and the vacuum pressures in the channels are controlled by the size of the apertures so that the substrate is adsorbed on the vacuum chuck.

### BACKGROUND

As the semiconductor industry introduces new generations of integrated circuits (IC) having higher performance and more functionality, the density of the elements forming the ICs increases, while the dimensions, sizes and spacing between components or elements are reduced. The semiconductor industry continues to improve the integration density of various electronic components (e.g., transistors, diodes, resistors, capacitors, etc.) by continual reductions in minimum feature size, which allow more components to be integrated into a given area.

There are a series of operations to carry out specified processes on the wafer W, such as a chemical vapor deposition. However, since the vacuum pressure of the vacuum chuck is concentrated in the center portion of the wafer, causing uneven vacuum pressure distribution, the risk of the wafer cracking due to excessive stress cannot be avoided.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a substrate processing device according to an embodiment of the present disclosure.

FIG. 2 is a top view of a vacuum chuck according to an embodiment of the present disclosure.

FIG. 3 is a schematic cross-sectional view of a substrate carrying unit according to an embodiment of the present disclosure.

FIG. 4 is a schematic diagram of a substrate placed flat on the vacuum chuck in FIG. 3.

FIG. 5 is a schematic cross-sectional view of the annular walls on the vacuum chuck.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly.

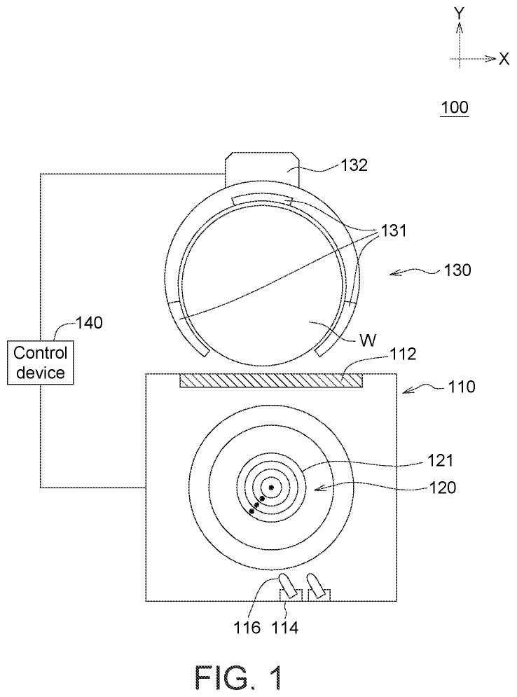

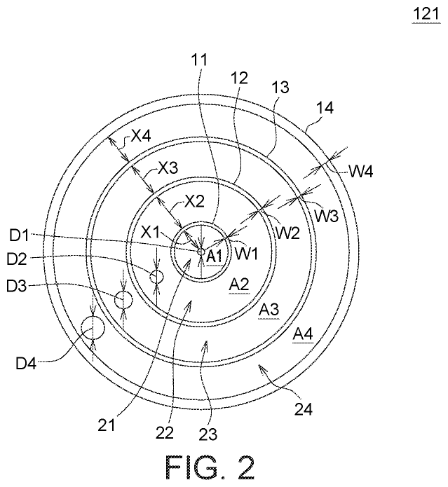

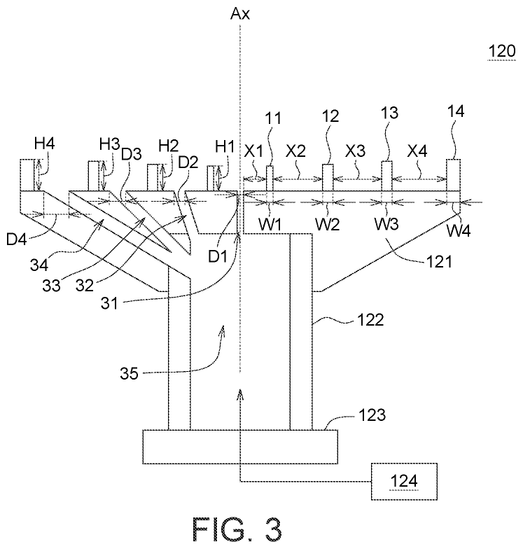

Referring to FIGS. 1, 2 and 3, the structure of the substrate processing device 100 and internal components thereof according to some embodiments will be described as follows. FIG. 1 is a schematic diagram of a substrate processing device 100 according to an embodiment of the present disclosure. FIG. 2 is a top view of a vacuum chuck 121 according to an embodiment of the present disclosure. FIG. 3 is a schematic cross-sectional view of a substrate carrying unit 120 according to an embodiment of the present disclosure. As shown in FIGS. 1, 2 and 3, the substrate processing device 100 includes a processing chamber 110, a substrate carrying unit 120 and a substrate pick-and-place device 130. The processing chamber 110 has a gate entrance 112 for the substrate pick-and-place device 130 to put a substrate (such as a wafer W) into or take out a substrate from the processing chamber 110. The processing chamber 110 may perform a series of operations to carry out specified processes on the wafer W. For example, the substrate processing device 100 may perform chemical vapor deposition, physical vapor deposition, or other operations on the wafer W.

The substrate carrying unit 120 is disposed in the processing chamber 110 to rotatably hold the wafer W. The substrate carrying unit 120 includes a vacuum chuck 121, a shaft part 122 and a driving part 123.

The vacuum chuck 121 absorbs and holds the wafer W by vacuum suction. The vacuum chuck 121 is smaller than the diameter of the wafer W. The vacuum chuck 121 absorbs and holds the center portion of the bottom surface of the wafer W. The shaft part 122 has a rotation axis Ax, and the shaft part 122 is rotated by a driving part 123 such as a motor. That is, the driving part 123 can drive the shaft part 122 to rotate, so that the wafer W held on the vacuum chuck 121 rotates around the rotation axis Ax.

The shaft portion 122 supports the vacuum chuck 121 horizontally at the front end. The driving part 123 is connected to the base end part of the shaft part 122. The driving part 123 rotates the shaft part 122 around the vertical axis, and raises and lowers the shaft part 122 and the vacuum chuck 121 supported by the shaft part 122.

The processing chamber 110 also includes a nozzle arm 114 and a nozzle 116. The nozzle arm 114 extends in the horizontal direction (here, the Y-axis direction) to support the nozzle 116 at the front end. The nozzle 116 is arranged above the wafer W with the discharge port facing downward, and discharges processing liquids such as chemical solution and rinse liquid onto the upper surface of the wafer W. Examples of the chemical solution include hydrofluoric acid (HF), dilute hydrofluoric acid (DHF), fluoronitric acid, and the like. In addition, fluorine is a mixture of hydrofluoric acid (HF) and nitric acid (HNO₃). In addition, the rinse liquid is, for example, deionized water (DIW). The nozzle arm 114 moves, for example, in the horizontal direction (here, the X- or Y axis direction), thereby allowing the nozzle 116 to move between a processing position above the peripheral area of the wafer W and a standby position outside the processing position.

In addition, the substrate processing device 100 also includes a control device 140, such as a computer, which includes a CPU (central processing unit), ROM (Read Only Memory), RAM (Random Access Memory), input and output terminals, and the likes. The control device 140 controls the processing chamber 110, the substrate pick-and-place device 130 and the substrate carrying unit 120 by reading and executing the program stored in the memory. For example, the control device 140 can control the substrate pick-and-place device 130 to move the wafer W into the processing chamber 110 or move the wafer W out of the processing chamber 110, perform various liquid processes on the wafer W moved into the processing chamber 110, perform a rinse process on the wafer W processed by various liquid processes, and perform a drying process on the wafer W processed by the rinse process.

Generally speaking, semiconductor manufacturing processes involve many process steps in which layers of various materials are stacked one after another and patterned accordingly. Typically, some of these layers may be formed by a so-called spin coating process, in which a fluid or other flowable material is deposited on top of the central region of the semiconductor wafer W. In practice, the semiconductor wafer W spins or rotates appropriately around the central axis 122, and the centrifugal force causes the deposited material to diffuse outward from the central region where it was originally deposited and/or flow toward the periphery of the semiconductor wafer W. Using traditional spin coating technology and/or equipment, there is a risk that the semiconductor wafer W will be dented downward due to the suction force of the vacuum chuck 121. For example, the contact area between the dented semiconductor wafer W and the central area of the vacuum chuck 121 is larger than the contact area between the semiconductor wafer W and the periphery area of the vacuum chuck 121. The substrate processing device 100 disclosed herein can solve the above-mentioned problem of inconsistent contact areas between the central area of the vacuum chuck 121 and the wafer W and between the periphery area of the vacuum chuck 121 and the wafer W.

In addition, the substrate pick-and-place device 130 can complete the pick-and-place operation of the wafer W through the gripper 131, the robotic arm 132 and the numerical control machine. Although the pick-and-place numerical control machine and the robotic arm 132 are not shown clearly in the embodiments, but the pick-and-place machine and the robotic arm 132 are known devices and will not be described again here. In short, the robotic arm 132 is configured to control the horizontal movement, vertical movement, rotation and/or tilt of the gripper 131. The pick-and-place numerical control machine is configured to control the robotic arm 132 to move to the place where the wafer W is placed, so as to pick and place another wafer W.

In some embodiments, the substrate (i.e., wafer) may comprise glass, silicon, germanium, a printed circuit board (PCB) and the like, as examples. The width of the substrate may be between about a few mils to several tens of mils and may comprise a diameter of about 300 mm in some embodiments. The substrate can function as a semiconductor wafer W during the packaging of semiconductor devices or dies.

In some embodiments, the substrate may be a bulk semiconductor wafer. For example, the substrate may include a compound semiconductor. Compound semiconductors may include gallium nitride, gallium arsenide, silicon carbide, indium arsenide, indium phosphide, other suitable materials, or combinations thereof. But in other embodiments, the substrate may include alloy semiconductors, such as silicon germanium, silicon germanium carbide, gallium arsenic phosphide, or gallium indium phosphide). In other embodiments, the substrate may include a silicon-on-insulator (SOI) or germanium-on-insulator (GOI) substrate. The SOI substrate can be made by separation by implantation of oxygen technology, wafer bonding technology, other suitable technologies, or a combination of the above.

In some embodiments, the vacuum chuck 121 may have a plurality of annular walls 11-14 distributed in concentric circles, and the annular walls 11-14 are disposed on the upper surface of the vacuum chuck 121 from the inside to the outside. The upper surface of the vacuum chuck 121 is divided into a plurality of annular areas A1-A4. As shown in FIGS. 2 and 3, for example, there are four or more annular walls 11-14. The annular walls include a first annular wall 11, a second annular wall 12, a third annular wall 13, and a fourth annular wall 14. The internal space enclosed by the first annular wall 11 defines a first chamber 21, and the internal space enclosed by the first annular wall 11 and the second annular wall 12 defines a second chamber 22. The internal space surrounded by the second annular wall 12 and the third annular wall 13 defines a third chamber 23, the internal space surrounded by the third annular wall 13 and the fourth annular wall 14 defines a fourth chamber 24, and so forth.

The first chamber 21 has a first critical dimension (for example, the distance X1 from the center point of the vacuum chuck 121 to the first annular wall 11, that is, the radius). The first critical dimension is, for example, greater than 5 mm. The second chamber 22 has a second critical dimension (for example, the distance X2 from the first annular wall 11 to the second annular wall 12). The second critical dimension is, for example, greater than 5 mm or greater than 10 mm. The third chamber 23 has a third critical dimension (for example, the distance X3 from the second annular wall 12 to the third annular wall 13). The third critical dimension is, for example, greater than 5 mm, greater than 10 mm, or greater than 15 mm. The fourth chamber 24 has a fourth critical dimension (for example, the distance X4 from the third annular wall 13 to the fourth annular wall 14). The fourth critical dimension is, for example, greater than 5 mm or greater than 10 mm or greater than 15 mm or greater than 20 mm.

In some embodiments, the first distance X1 is less than, equal to, or substantially equal to the second distance X2. The second distance X2 is less than, equal to, or substantially equal to the third distance X3. The third distance X3 is less than, equal to, or substantially equal to the fourth distance X4. As shown in FIGS. 2 and 3, the first distance X1 is smaller than the second distance X2, the second distance X2 is smaller than the third distance X3, and the third distance X3 is smaller than the fourth distance X4, that is, X1<X2<X3<X4.

In some embodiments, a vacuum pump 124 is connected with a corresponding channel to extract air in each of the chambers 21-24. As shown in FIG. 3, the first chamber 21 is connected with the first channel 31 inside the vacuum chuck 121. The first channel 31 has a first suction inlet and a first outlet. The first suction inlet is located in the first annular area A1 in the middle of the vacuum chuck 121, the first outlet is connected to the hollow part 35 of the shaft part 122. In addition, the vacuum pump 124 can be connected to the first channel 31 through the hollow part 35 of the shaft portion 122 so that the wafer W can be adsorbed to the vacuum chuck 121 during a vacuuming period. The first suction inlet has a first aperture D1, and the first aperture D1 is, for example, greater than 1 mm.

As shown in FIG. 3, the second chamber 22 is connected with the second channel 32 inside the vacuum chuck 121. The second channel 32 has a second suction inlet and a second outlet. The second suction inlet is located in the second annular area A2 of the vacuum chuck 121 and the second outlet are connected to the hollow part 35 of the shaft portion 122. In addition, the vacuum pump 124 can be connected to the second channel 32 through the hollow part 35 of the shaft portion 122 so that the wafer W can be adsorbed to the vacuum chuck 121 during a vacuuming period. The second suction port has a second aperture D2, and the second aperture D2 is, for example, greater than 1 mm or greater than 3 mm.

As shown in FIG. 3, the third chamber 23 is connected with the third channel 33 inside the vacuum chuck 121. The third channel 33 has a third suction inlet and a third outlet. The third suction inlet is located in the third annular area A3 of the vacuum chuck 121 and the third outlet is connected to the hollow part 35 of the shaft portion 122. In addition, the vacuum pump 124 can be connected to the third channel 33 through the hollow part 35 of the shaft portion 122 so that the wafer W can be adsorbed to the vacuum chuck 121 during a vacuuming period. The third suction port has a third aperture D3, and the third aperture D3 is, for example, greater than 1 mm, greater than 3 mm, or greater than 5 mm.

As shown in FIG. 2, the fourth chamber 24 is connected with the fourth channel 34 inside the vacuum chuck 121. The fourth channel 34 has a fourth suction inlet and a fourth outlet. The fourth suction inlet is located in the fourth annular area A4 of the vacuum chuck 121 and the fourth outlet is connected to the hollow part 35 of the shaft portion 122. In addition, the vacuum pump 124 can be connected to the fourth channel 34 through the hollow part 35 of the shaft portion 122 so that the wafer W can be adsorbed to the vacuum chuck 121 during a vacuuming period. The fourth suction port has a fourth aperture D1, and the fourth aperture D1 is, for example, greater than 1 mm, greater than 3 mm, greater than 5 mm, or greater than 7 mm.

In some embodiments, the first aperture D1 is less than, equal to, or substantially equal to the second aperture D2. The second aperture D2 is smaller than, equal to, or substantially equal to the third aperture D3. The third aperture D3 is smaller than, equal to, or substantially equal to the fourth aperture D4. As shown in FIG. 2, the first aperture D1 is smaller than the second aperture D2, the second aperture D2 is smaller than the third aperture D3, and the third aperture D3 is smaller than the fourth aperture D4, that is, D1<D2<D3<D4.

When the vacuum pump 124 performs a vacuuming operation on the wafer W located on the vacuum chuck 121, the vacuum pressure P in each chamber 21-24 remains consistent, and the air flow in each chamber 21-24 is adjusted according to size of the apertures D1-D4 of the corresponding channels 31-34. Since the size of each aperture conforms to the relationship of D1<D2<D3<D4, the vacuum pressure distributions of the channels 33 and 34 close to the outside are even with the vacuum pressure distributions of the channels 31 and 32 close to the inside, so as to avoid the vacuum chuck 121 from forming different vacuum pressure distributions within each of the channels 31-34.

From the above description, it can be known that the vacuum chuck 121 that forms a uniform vacuum pressure distribution can generate a uniform vacuum adsorption force on the wafer W. For example, the vacuum suction force of the vacuum chuck 121 on the central area of the wafer W can be equal to the vacuum suction force of the vacuum chuck 121 on the peripheral area of the wafer W, so as to avoid the risk of cracking of the central area of the wafer W due to excessive stress. Since the peripheral area of the wafer W is larger than the central area of the wafer W, the area required for adsorption on the periphery of the wafer W is relatively large. Therefore, the present disclosure provides a channel 34 with a larger aperture D4 to adsorb the periphery of the wafer W, resulting in a better adsorption effect.

In some embodiments, each of annular walls 11-14 has the same or different wall thickness. The wall thickness refers to the width of each of the annular walls 11-14. As shown in FIGS. 2 and 3, the first annular wall 11 has a first width W1 (for example, the distance between the inner wall and the outer wall). The first width W1 is larger than 2 mm, for example. The second annular wall 12 has a second width W2 (for example, the distance between the inner wall and the outer wall). The second width W2 is, for example, greater than 2 mm or greater than 4 mm. The third annular wall 13 has a third width W3 (for example, the distance between the inner wall and the outer wall). The third width W3 is, for example, greater than 2 mm, greater than 4 mm, or greater than 6 mm. The fourth annular wall 14 has a fourth width W4 (for example, the distance between the inner wall and the outer wall). The fourth width W4 is, for example, greater than 2 mm, greater than 4 mm, greater than 6 mm, or greater than 8 mm.

In some embodiments, the first width W1 is less than, equal to, or substantially equal to the second width W2. The second width W2 is less than, equal to, or substantially equal to the third width W3. The third width W3 is less than, equal to, or substantially equal to the fourth width W4. As shown in FIGS. 2 and 3, the first width W1 is smaller than the second width W2, the second width W2 is smaller than the third width W3, and the third width W3 is smaller than the fourth width W4, that is, W1<W2<W3<W4.

The greater the widths W1-W4 of the annular walls 11-14, the greater the supported area of the wafer W. Since the peripheral area of the wafer W is large, the area that needs to be supported at the peripheral area of the wafer W is relatively large. Therefore, the present disclosure provides an annular wall 14 with a larger width W4 to support the peripheral area of the wafer W, resulting in a better support effect.

In some embodiments, each of the annular walls 11-14 has the same or different vertical lengths. The vertical length refers to the height of the annular walls 11-14, extending vertically upward from the top surface of the vacuum chuck 121. As shown in FIG. 3, the first annular wall 11 has a first height H1 (for example, the distance between the bottom surface and the top surface), and the first height H1 is, for example, greater than 5 mm. The second annular wall 12 has a second height H2 (for example, the distance between the bottom surface and the top surface). The second height H2 is, for example, greater than 5 mm or greater than 6 mm. The third annular wall 13 has a third height H3 (for example, the distance between the bottom surface and the top surface). The third height H3 is, for example, greater than 5 mm, greater than 6 mm, or greater than 7 mm. The fourth annular wall 14 has a fourth height H4 (for example, the distance between the bottom surface and the top surface). The fourth height H4 is, for example, greater than 5 mm, greater than 6 mm, greater than 7 mm, or greater than 8 mm.

In some embodiments, the first height H1 is less than, equal to, or substantially equal to the second height H2. The second height H2 is less than, equal to, or substantially equal to the third height H3. The third height H3 is less than, equal to, or substantially equal to the fourth height H4. As shown in FIG. 3, the first height H1 is less than the second height H2, the second height H2 is less than the third height H3, and the third height H3 is less than the fourth height H4, that is, H1<H2<H3<H4.

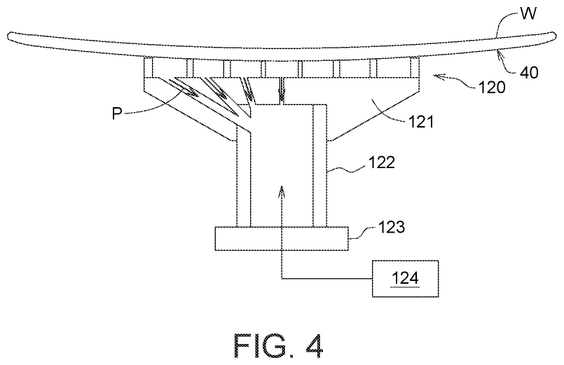

As shown in FIG. 4, the substrate (e.g., wafer W) is placed flat on the vacuum chuck 121 in FIG. 3. The wafer W is uneven due to warping. Since the peripheral area of the wafer W is warped upward, the bottom surface of the wafer W cannot form a flat bottom surface. In order to increase the contact area between the non-flat bottom surface 40 of the wafer W and the respective annular walls 11-14 of the vacuum chuck 121, the contour formed by the top surfaces of the annular walls 11-14 of the vacuum chuck 121 and the shape of the non-flat bottom surface 40 of the wafer W is matched so that the non-flat bottom surface 40 of the wafer W can be in complete contact or nearly complete contact with the top surfaces of the annular walls 11-14 of the vacuum chuck 121. For example, in accordance with the curvature or slope of the non-flat bottom surface 40 of the wafer W, the top surface profiles of the annular walls 11 and the shape of the non-flat bottom surface 40 have the same or similar curvature or slope to reduce the gap existing therebetween. Since the wafer W is well supported, even if the wafer W has innate defects or warpage defects caused by the thermal process (i.e., non-flat bottom surface 40), the contact area between the non-flat bottom surface 40 of the wafer W and the annular walls 11-14 of the vacuum chuck 121 can still be effectively increased to reduce the risk of the wafer W being broken due to excessive stress.

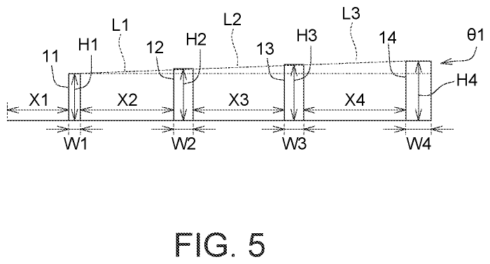

In some embodiments, the widths W1-W4 of the annular walls 11-14 increase as the heights H1-H4 of the annular walls 11-14 increase, and the height increase ratios of two adjacent annular walls 11-14 are positively correlated with the distances X1 to X4 between adjacent two annular walls 11-14. As shown in FIG. 5, the ratio (W1/H1) of the width W1 and the height H1 of the first annular wall 11 is substantially the same as the ratio (W2/H2) of the width W2 and the height H2 of the second annular wall 12. The ratio (W2/H2) of the width W2 and the height H2 of the second annular wall 12 is substantially the same as the ratio (W3/H3) of the width W3 and the height H3 of the third annular wall 13. The ratio (W3/H3) of the width W3 and the height H3 is substantially the same as the ratio (W4/H4) of the width W4 and the height H4 of the fourth annular wall 14, and so on. In addition, as shown in FIG. 5, the height increase ratio of the first annular wall 11 and the second annular wall 12 is represented by H2-H1, and the distance between the first annular wall 11 and the second annular wall 12 is represented by X2, (H2-H1)/X2 is configured to represent the first slope L1 (shown as the dotted line in FIG. 5). The height increase ratio of the second annular wall 12 and the third annular wall 13 is represented by H3-H2, and the distance between the second annular wall 12 and the third annular wall 13 is represented by X3, (H3-H2)/X3 is configured to represent the second slope L2 (shown as the dotted line in FIG. 5). The height increase ratio of the third annular wall 13 and the fourth annular wall 14 is represented by H4-H3, and the distance between the third annular wall 13 and the fourth annular wall 14 is represented by X4, (H4-H3)/X4 is configured to represent the third slope L3 (shown as the dotted line in FIG. 5).

Without considering the increase in the widths of each of the annular walls 11-14, or the widths of each of the annular walls 11-14 are negligible, the above-mentioned first slope L1, second slope L2 and third slope L3 can be equal or adjusted according to actual conditions. The first slope L1, the second slope L2 and the third slope L3 are expressed in radian or as an angle θ1 (sine angle) corresponding to the radian, for example, greater than 0 degrees and between 0 degree and 5 degrees. Assume that the non-flat bottom surface 40 of the wafer W is a curved surface with a changing curvature. The first slope L1, the second slope L2 and the third slope L3 can be different or increase in equal proportions. For example, the angle θ1 corresponding to the first slope L1 is between 1 degree and 2 degrees, the angle θ1 corresponding to the second slope L2 is between 2 degrees and 3 degrees, the angle θ1 corresponding to the third slope L3 is between 3 degrees and 5 degrees, and so on. In another embodiment, the angles θ1 corresponding to the first slope L1 and the second slope L2 are between 1 degree and 3 degrees, and the angle θ1 corresponding to the third slope L3 is between 3 and 5 degrees.

The present disclosure relates to a substrate carrying unit and a substrate processing device having the same, which are configured to improve the problem of wafer cracking due to excessive stress. Since the vacuum suction force of the vacuum chuck on the central area of the wafer can be equal to the vacuum suction force of the vacuum chuck on the peripheral area of the wafer, the risk of cracking on the central area of the wafer due to excessive stress can be avoided. Therefore, the present disclosure provides a better adsorption effect to adsorb the periphery of the wafer on the vacuum chuck.

According to some embodiments of the present disclosure, a substrate processing device is provided, including a processing chamber and a substrate carrying unit. The substrate carrying unit is disposed in the processing chamber. The substrate carrying unit includes a vacuum chuck, a shaft part and a driving part. The vacuum chuck adsorbs and holds a substrate through a vacuum suction. The shaft part has a rotation axis, and the shaft part is configured to support the vacuum chuck. The driving part is configured to drive the vacuum chuck and the shaft part to rotate around the rotation axis, wherein the vacuum chuck has a plurality of channels with different apertures inside, and the vacuum pressures in the channels are controlled by the size of the apertures so that the substrate is adsorbed on the vacuum chuck.

According to some embodiments of the present disclosure, a substrate processing device is provided, including a processing chamber and a substrate carrying unit. The substrate carrying unit is disposed in the processing chamber. The substrate carrying unit includes a vacuum chuck, a shaft part and a driving part. The vacuum chuck adsorbs and holds a substrate through a vacuum suction. The shaft part has a rotation axis, and the shaft part is configured to support the vacuum chuck. The driving part is configured to drive the vacuum chuck and the shaft part to rotate around the rotation axis, wherein the vacuum chuck has a plurality of annular walls with different widths, and the contact areas between the annular walls and the substrate are controlled according to the size of the widths so that the substrate is adsorbed on the vacuum chuck.

According to some embodiments of the present disclosure, a substrate carrying unit is provided, including a vacuum chuck, a shaft part and a driving part. The vacuum chuck adsorbs and holds a substrate through a vacuum suction. The shaft part has a rotation axis, and the shaft part is configured to support the vacuum chuck. The driving part is configured to drive the vacuum chuck and the shaft part to rotate around the rotation axis, wherein the vacuum chuck has a plurality of annular walls with different heights, and the contact areas between the annular walls and the substrate are controlled by the size of the heights so that the substrate is adsorbed on the vacuum chuck.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A substrate processing device, comprising:
a processing chamber; and
a substrate carrying unit disposed in the processing chamber, the substrate carrying unit comprising:
a vacuum chuck for adsorbing and holding a substrate through a vacuum suction;
a shaft part having a rotation axis, the shaft part is configured to support the vacuum chuck; and
a driving part for driving the vacuum chuck and the shaft part to rotate around the rotation axis, wherein the vacuum chuck has a plurality of channels with different apertures, and vacuum pressures inside the channels are controlled by the size of the apertures so that the substrate is adsorbed on the vacuum chuck.

2. The substrate processing device as claimed in claim 1, further comprising a vacuum pump for extracting air from the channels, and the vacuum pump communicates with the channels through a hollow part of the shaft.

3. The substrate processing device as claimed in claim 1, wherein the vacuum chuck has a plurality of annular areas, the annular areas are distributed in concentric circles, and each of suction inlets of the channels are respectively located in the annular areas.

4. The substrate processing device as claimed in claim 3, wherein the apertures of the suction inlets of the channels increase sequentially from a center of the vacuum chuck outward.

5. A substrate processing device, comprising:
a processing chamber; and
a substrate carrying unit disposed in the processing chamber, the substrate carrying unit comprising:
a vacuum chuck for adsorbing and holding a substrate through a vacuum suction;
a shaft part having a rotation axis, wherein the shaft part is configured to support the vacuum chuck; and
a driving part configured to drive the vacuum chuck and the shaft part to rotate around the rotation axis, wherein the vacuum chuck has a plurality of annular walls with different widths, and contact areas between the annular walls and the substrate are controlled according to the size of the widths so that the substrate is adsorbed on the vacuum chuck.

6. The substrate processing device as claimed in claim 5, wherein the vacuum chuck has a plurality of channels with different apertures, and vacuum pressures inside the channels are controlled by the size of the apertures.

7. The substrate processing device as claimed in claim 6, further comprising a vacuum pump for extracting air from the channels, and the vacuum pump communicates with the channels through a hollow part of the shaft.

8. The substrate processing device as claimed in claim 6, wherein the vacuum chuck has a plurality of annular areas, the annular areas are distributed in concentric circles, and each of suction inlets of the channels are respectively located in the annular areas.

9. The substrate processing device as claimed in claim 8, wherein the apertures of the suction inlets of the channels increase sequentially from a center of the vacuum chuck outward.

10. The substrate processing device as claimed in claim 5, wherein the annular walls are distributed in concentric circles and disposed on the upper surface of the vacuum chuck to define a plurality of chambers, wherein distances between the annular walls increases sequentially from a center of the vacuum chuck outward.

11. The substrate processing device as claimed in claim 10, wherein heights of the annular walls increase sequentially from the center of the vacuum chuck outward.

12. A substrate carrying unit, comprising:
a vacuum chuck for adsorbing and holding a substrate through a vacuum suction;
a shaft part having a rotation axis, wherein the shaft part is configured to support the vacuum chuck; and
a driving part configured to drive the vacuum chuck and the shaft part to rotate around the rotation axis, wherein the vacuum chuck has a plurality of annular walls with different heights, and contact areas between the annular walls and the substrate are controlled by size of the heights so that the substrate is adsorbed on the vacuum chuck.

13. The substrate carrying unit as claimed in claim 12, wherein the vacuum chuck has a plurality of channels with different apertures, and the vacuum pressure in the channels is controlled by the size of the apertures.

14. The substrate carrying unit as claimed in claim 13, further comprising a vacuum pump for extracting air from the channels, and the vacuum pump communicates with the channels through the hollow part of the shaft.

15. The substrate carrying unit as claimed in claim 13, wherein the vacuum chuck has a plurality of annular areas, the annular areas are distributed in concentric circles, and each of suction inlets of the channels are respectively located in the annular areas.

16. The substrate carrying unit as claimed in claim 15, wherein the apertures of the suction inlets of the channels increase sequentially from a center of the vacuum chuck outward.

17. The substrate carrying unit of claim 12, wherein the annular walls are distributed in concentric circles and disposed on an upper surface of the vacuum chuck to define a plurality of chambers, wherein distances between the walls increases sequentially from a center of the vacuum chuck outward.

18. The substrate carrying unit as claimed in claim 17, wherein heights of the annular walls increase sequentially from the center of the vacuum chuck outward.

19. The substrate carrying unit as claimed in claim 17, wherein widths of the annular walls increases sequentially from the center of the vacuum chuck outward.

20. The substrate carrying unit as claimed in claim 12, wherein the substrate has a non-flat bottom surface, and top surfaces of the annular walls form a contour that matches a shape of the non-flat bottom surface of the substrate.
